(19) United States
(12) Patent Application Publication
(10) Pub. No.: US 2022/0197130 A1
(43) Pub. Date: Jun. 23, 2022

(54) PHOTOMASK

(71) Applicants: DIC Corporation, Tokyo (JP); TOPIC Co., LTD., Kawaguchi-city, Saitama (JP)

(72) Inventors: Takahiro Echigoya, Kawaguchi-city (JP); Shinobu Ikeda, Kawaguchi-city (JP); Masaharu Sasaki, Kawaguchi-city (JP); Yoshinori Katayama, Tokyo (JP)

(73) Assignees: DIC Corporation, Tokyo (JP); TOPIC Co., LTD., Kawaguchi-city, Saitama (JP)

(21) Appl. No.: 17/601,523

(22) PCT Filed: Oct. 31, 2019
(86) PCT No.: PCT/JP2019/042744

§ 371 Date: Oct. 5, 2021

(30) Foreign Application Priority Data
Apr. 10, 2019 (JP) 2019-074681

(51) Int. Cl. G03F 1/38

(52) U.S. Cl. CPC G03F 1/38

(57) ABSTRACT

A photomask excellent in durability and exposure efficiency is provided, which is obtained by a simple manufacturing method at a low cost, exhibits sufficient ESD-suppressing effect, causes no destruction of an exposure pattern, and has satisfactory exposure efficiency. The photomask comprises a light-shielding film formed into a pattern for shielding a photoresist film from exposure to light, formed on a surface of a transparent substrate. A coating layer including a thiophene-based conductive resin is formed on the transparent substrate having the light-shielding film formed thereon. The sheet resistance at a surface of the photomask having the coating layer including a thiophene-based conductive resin is smaller than 10¹¹Ω/□.

### TECHNICAL FIELD

The present invention relates to a photomask in which electrostatic discharge is suppressed.

### BACKGROUND ART

Conventionally, when wiring boards for use in electronic devices are manufactured, a photomask to be transferred is produced and an exposure pattern of the photomask is transferred to a photoresist.

In transfer, when the photomask is brought into contact with or brought closer to the photoresist and thereafter stripped off from the photoresist, static electricity is created between the photomask and the photoresist during separation.

This static electricity may sometimes cause electrostatic discharge (hereinafter ESD). The built-up static electricity causes discharge between patterns in the exposure pattern or between the pattern and the resist and destroys the exposure pattern drawn on the photomask.

Destruction of the exposure pattern leads to failure of subsequent accurate transfer, and therefore photomasks that do not cause electrostatic discharge (ESD) have been sought for.

Methods for protecting an exposure pattern of a photomask from electrostatic discharge (ESD) have been developed (for example, see PTL 1 and PTL 2).

PTL 1 describes a photomask having a coating layer of polyvinyl alcohol resin on a mask pattern that is an exposure pattern.

PTL 2 describes a photomask having a conductive transparent resin film electrically connected to a ground end on a mask pattern.

### CITATION LIST

### Patent Literature

PTL 1: Japanese Unexamined Patent Application Publication No. S60-004944
PTL 2: Japanese Unexamined Patent Application Publication No. 2005-189665

### SUMMARY OF INVENTION

### Technical Problem

However, the photomasks described in PTLs 1 and 2 above fail to provide sufficient ESD-suppressing effect. Moreover, the photomasks may disadvantageously provide reduced light transmittance and compromised exposure efficiency.

An object of the present invention is to provide a photomask excellent in durability and exposure efficiency, which is obtained by a simple manufacturing method at a low cost, exhibits sufficient ESD-suppressing effect, causes no destruction of the exposure pattern, and has satisfactory exposure efficiency.

### Solution to Problem

The inventors of the present invention have conducted elaborate study to solve the problem above and found that the problem can be solved by a photomask that has a coating layer including a thiophene-based conductive resin formed on a transparent substrate having a light-shielding film formed thereon, and has a sheet resistance equal to or smaller than a certain value. This finding has led to completion of the present invention.

Specifically, the present invention includes the following aspects.

[1] A photomask comprising a light-shielding film formed on a surface of a transparent substrate, the light-shielding film being formed into a pattern for shielding a photoresist film from exposure to light, in which

the transparent substrate having the light-shielding film formed thereon has a coating layer including a thiophene-based conductive resin, and

a sheet resistance at a surface of the photomask having the coating layer including a thiophene-based conductive resin is smaller than 10¹¹Ω/□.

[2] The photomask according to [1], in which the photomask having the coating layer including a thiophene-based conductive resin has a transmittance of 80% or higher to light having a wavelength of 365 nm.

[3] The photomask according to [1] or [2], further comprising a resin covering layer on the coating layer including a thiophene-based conductive resin.

[4] A method of manufacturing the photomask according to [1] or [2], the method comprising, in a photomask comprising a light-shielding film formed into a pattern for shielding a photoresist film from exposure to light, formed on a surface of a transparent substrate, forming a coating layer including a thiophene-based conductive resin on the transparent substrate having the light-shielding film formed thereon.

[5] The method of manufacturing the photomask according to [4], further comprising forming a resin covering layer on the coating layer including a thiophene-based conductive resin.

[6] A method of manufacturing an electronic component, the method comprising performing exposure using the photomask according to any one of [1] to [3].

[7] An electronic component manufactured using the photomask according to any one of [1] to [3].

### Advantageous Effects of Invention

The present invention provides a photomask excellent in durability and exposure efficiency, which is obtained by a simple manufacturing method at a low cost, exhibits sufficient ESD-suppressing effect, causes no destruction of the exposure pattern, and has satisfactory exposure efficiency.

### BRIEF DESCRIPTION OF DRAWINGS

FIG. 1 is a schematic sectional view illustrating an aspect of a layer configuration of a photomask of the present invention.

FIG. 2 is a schematic sectional view illustrating another aspect of a layer configuration of the photomask of the present invention.

FIG. 3 is a diagram illustrating a mask pattern shape in a photomask used in Examples.

FIG. 4 is a diagram illustrating a mask pattern section particularly observed in the photomask in FIG. 3.

FIG. 5 is a photograph illustrating a normal mask pattern shape before electrostatic discharge occurs.

FIG. 6 is a photograph illustrating a destroyed mask pattern shape after electrostatic discharge occurs.

### DESCRIPTION OF EMBODIMENTS

A photomask, a method of manufacturing the photomask, and a method of manufacturing an electronic component using the photomask according to the present invention will be described in detail below. However, a description of the following constituent elements is given as an illustrative example of embodiments of the present invention, and the present invention is not limited to such a description.

(Photomask)

A photomask of the present invention has a coating layer including a thiophene-based conductive resin on a transparent substrate having a light-shielding film formed thereon.

A light-shielding film formed into a pattern for shielding a photoresist film from exposure to light is formed on a surface of the transparent substrate.

The sheet resistance at a surface of the photomask having a coating layer including a thiophene-based conductive resin is smaller than 10¹¹Ω/□.

The photomask is used such that the light-shielding film (pattern formation film) side of the photomask is brought into intimate contact with a front surface (photosensitive layer) side of a target to be photoetched or the photomask is arranged to face the target with a minute gap between the front surface side of the target and the light-shielding film side of the photomask.

<Transparent Substrate>

Any desired transparent substrate that satisfies the sheet resistance defined in the present invention can be used as appropriate according to the purposes without limitation of the kind and the substrate size of the transparent substrate.

Examples of the kind of transparent substrate include glass substrates, and examples of the glass substrates include soda-lime glass and silica glass. Since silica glass has a high transmittance to UV that is a high energy wave, soda-lime glass is preferred in terms of preventing degradation of the conductive resin more.

The thickness of the transparent substrate can be selected as appropriate according to the purposes and is preferably, for example, in a range of 0.5 mm to 30 mm.

<Light-Shielding Film>

The light-shielding film is formed on the transparent substrate and has a pattern according to the purposes.

An example of the kind of light-shielding film is a light-shielding film including a material containing chromium.

Commonly known methods such as vacuum evaporation and sputtering can be used as a method of producing a chromium light-shielding film.

Specifically, examples of such a material include chromium as pure metal, and chromium compounds such as chromium oxide (CrO), chromium nitride (CrN), chromium carbide (CrC), chromium oxynitride (CrON), chromium oxycarbide (CrOC), chromium nitride carbide (CrNC), and chromium oxynitride carbide (CrONC).

The film thickness of the light-shielding film can be selected as appropriate according to the purposes and, for example, preferably in the range of 50 nm to 250 nm, more preferably in the range of 90 nm to 110 nm.

Common photomask forming methods can be used as a method of obtaining a photomask comprising a light-shielding film formed into a pattern on a transparent substrate.

For example, a photomask blank having a light-shielding film onto a transparent substrate is fabricated by evaporating chromium on a glass substrate. Subsequently, a resist (photosensitive resin) is uniformly applied to a surface of the photomask blank and patterned by laser light or electron beam exposure. Subsequently, using this resist pattern as an etching mask, the light-shielding film is etched to form a mask pattern, and the resist pattern is then removed. In this way, a photomask comprising a light-shielding film formed into a pattern on a transparent substrate can be obtained.

In the production method described above, the resist at portions exposed to laser light or electron beams is removed, but the portions not exposed may be removed depending on the kinds of resist. The photomask may be formed in either manner.

<Coating Layer of Conductive Resin>

The photomask of the present invention is a photomask comprising a light-shielding film formed into a pattern on a transparent substrate, in which a coating layer including a thiophene-based conductive resin is further formed on the transparent substrate having the light-shielding film formed thereon.

Any desired kind of thiophene-based conductive resin that satisfies the sheet resistance defined in the present invention can be used as appropriate according to the purposes without limitation. An example thereof is a resin including PEDOT (poly(3,4-ethylenedioxythiophene)) doped with PSS (polystyrene sulfonate).

Examples of the thiophene-based conductive resin include commercially available VERAZOL (registered trademark) and SEPLEGYDA (registered trademark).

The film thickness of the coating layer including a thiophene-based conductive resin can be selected as appropriate according to the purposes without limitation as long as the sheet resistance defined in the present invention is satisfied. The film thickness is, for example, preferably in the range of 1 nm to 1,000 nm, more preferably in the range of 10 nm to 400 nm.

The film thickness of the coating layer including a thiophene-based conductive resin may be measured by stripping off the coating layer and measuring the difference in thickness between the portion where the coating layer is not stripped off and the portion where it is stripped off, or by measuring the difference between thickness before stripping and the thickness after stripping.

The thickness can be measured using a laser scanning microscope (OLS4100 from Olympus Corporation).

A coating material containing a thiophene-based conductive resin is applied to the transparent substrate having the light-shielding film formed thereon to form a coating layer including a thiophene-based conductive resin on the transparent substrate having the light-shielding film formed thereon.

Methods commonly known as coating methods such as spray coating and spin coating can be used as a coating method.

The conditions of coating are adjusted as appropriate so that the photomask of the present invention exhibits a desired sheet resistance. For example, it suffices if the concentration of a thiophene-based conductive resin in the coating material containing the thiophene-based conductive resin is adjusted, or the coating layer formation condition or drying condition is adjusted.

A specific method of forming the coating layer including a thiophene-based conductive resin will be described later.

The coating layer including a thiophene-based conductive resin can contain, in addition to the thiophene-based conductive resin, an adjusting agent for adjusting the viscosity of the coating material and a variety of performance enhancers such as a booster contributing to enhancement of strength of the coating layer.

It is preferable that the coating layer including a thiophene-based conductive resin is formed to cover the entire light-shielding film having a pattern formed on the transparent substrate and cover almost the entire effective region on the transparent substrate, that is, a region irradiated with light during exposure.

This allows the mask pattern to be electrically conductive and also allows a portion not having the mask pattern formed thereon on the transparent substrate to be electrically conductive.

Forming the coating layer including a thiophene-based conductive resin can effectively eliminate a potential difference in the light-shielding film and can prevent destruction of the mask pattern otherwise caused by the occurrence of static electricity.

However, for a light-shielding film having conductivity, the thiophene-based conductive resin is not necessarily covered because, in the present invention, the thiophene-based conductive resin is provided for preventing destruction of the mask pattern due to the occurrence of static electricity.

<Layer Configuration of Photomask>

The photomask of the present invention has a coating layer including a thiophene-based conductive resin on a transparent substrate having a light-shielding film formed thereon.

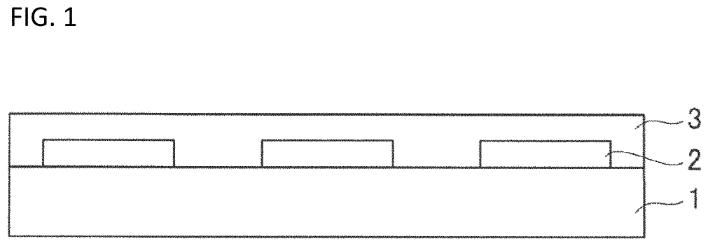

FIG. 1 illustrates an example of a schematic sectional view of a layer configuration of the photomask of the present invention.

In FIG. 1, a coating layer 3 including a thiophene-based conductive resin is formed on a transparent substrate 1 having a light-shielding film 2 formed thereon.

<Characteristics of Photomask>

<<Sheet Resistance>>

The photomask of the present invention has a sheet resistance smaller than 10¹¹Ω/□.

Since the sheet resistance is smaller than 10¹¹Ω/□, the photomask of the present invention has high ESD-suppressing effect and serves as a photomask capable of effectively preventing destruction of the exposure pattern.

As a measurement method of the sheet resistance, the surface resistance of the photomask can be measured using a 4-point probe measurement instrument. For example, a resistivity meter such as a 4-point probe system MCP-T610 from Mitsubishi Chemical Analytech Co., Ltd. or a ring electrode system MCP-HT450 from Mitsubishi Chemical Analytech Co., Ltd. can be used for measurement.

The 4-point probe measurement instrument for measuring a resistance is arranged on a measurement target in the photomask, and the sheet resistance is measured.

<<Light Transmittance>>

Furthermore, the photomask of the present invention is preferably a photomask that exhibits a transmittance of 80% or higher to light having a wavelength of 365 nm.

If the light transmittance is lower, the resolution and the fidelity of a transferred image may deteriorate and, in addition, the amount of exposure increases. To increase the exposure efficiency, it is necessary to set the light transmittance to a certain value or greater.

The photomask of the present invention having a coating layer including a thiophene-based conductive resin can exhibit a transmittance of 80% or higher to light having a wavelength of 365 nm, and a photomask with high exposure efficiency can be formed.

The transmittance of the photomask to light having a wavelength of 365 nm is preferably 80% or higher, more preferably 82% or higher, further preferably 84% of higher, particularly preferably 85% or higher.

The photomask of the present invention having a coating layer including a thiophene-based conductive resin can satisfy both of the sheet resistance smaller than 10¹¹Ω/□ and the transmittance of 80% or higher to light having a wavelength of 365 nm, and the photomask that satisfies both of the values is a photomask that satisfies both of the effect of suppressing electrostatic discharge and the effect of improving exposure efficiency.

The sheet resistance of the photomask is preferably 10²Ω/□ or higher because a high light transmittance is unable to be ensured with an excessively low sheet resistance.

The sheet resistance of the photomask is more preferably 5×102 W/O or higher in terms of acquiring the balance between sheet resistance and transmittance and providing a photomask that satisfies both of the effect of suppressing electrostatic discharge and the effect of improving exposure efficiency.

In the present invention, a photomask exhibiting a sheet resistance in the vicinity of 10⁶Ω/□ to 10⁸Ω/□ can be used favorably.

The transmittance can be measured using a spectrophotometer. For example, the transmittance can be measured using a spectrophotometer V-570 from JASCO Corporation.

In the photomask of the present invention, the transmittance is measured for a region where the coating layer including a conductive resin is formed on the transparent substrate at a portion in which the mask pattern is not formed.

<Other Aspect of Photomask>

In an aspect of the photomask of the present invention, a resin covering layer (also referred to as overcoat layer in the present description) may be further formed on the coating layer including a thiophene-based conductive resin.

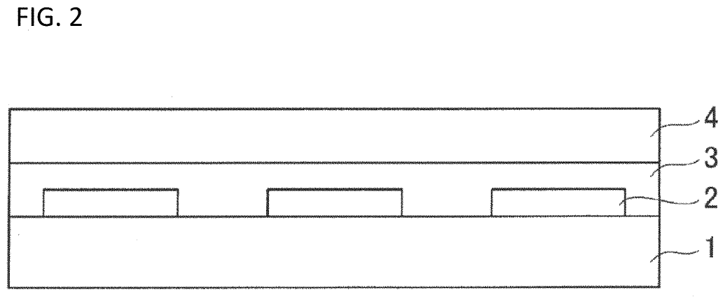

FIG. 2 illustrates an example of a schematic sectional view of a layer configuration of the photomask in an aspect of the present invention in which the resin covering layer is formed.

In FIG. 2, a coating layer 3 including a thiophene-based conductive resin is formed on a transparent substrate 1 having a light-shielding film 2 formed thereon, and a resin covering layer (overcoat layer) 4 is formed on the coating layer 3 including a thiophene-based conductive resin.

Forming the resin covering layer can protect the coating layer including a thiophene-based conductive resin and can provide a photomask with improved durability. The formation of the resin covering layer can prevent destruction of the exposure pattern more reliably even when the photomask is repeatedly used.

Any desired resin covering layer can be used as appropriate according to the purposes without limitation of the kind and the film thickness as long as the intimate contact, the adhesion, or the protecting performance is ensured.

Examples of the kind of resin covering layer include transparent resins such as polyester resins, silicone resins, and acrylic resins.

The film thickness of the resin covering layer is, for example, preferably in the range of 0.01 μm to 20 μm, more preferably in the range of 0.5 μm to 20 μm, further more preferably in the range of 1 μm to 6 μm.

<Method of Manufacturing Photomask>

The photomask comprising a light-shielding film formed into a pattern on a transparent substrate can be obtained by a common photomask forming method as described above.

The photomask of the present invention is manufactured by, in a photomask comprising a light-shielding film formed into a pattern for shielding a photoresist film from exposure to light, formed on a surface of a transparent substrate, forming a coating layer including a thiophene-based conductive resin on the transparent substrate having the light-shielding film formed thereon.

A method of forming a coating layer including a thiophene-based conductive resin on the transparent substrate having the light-shielding film formed thereon will be described below.

A coating material containing a thiophene-based conductive resin is applied to the transparent substrate having the light-shielding film formed thereon.

Before a coating material containing a thiophene-based conductive resin is applied, the transparent substrate having the light-shielding film formed thereon may be subjected to pretreatment such as cleaning. As pretreatment, for example, cleaning with an alkaline solution, cleaning with ultrapure water, scrub cleaning with a brush, or these cleanings in combination may be performed.

A coating method such as spin coating, spray coating, dip coating, or curtain coating may be used as a coating method.

The concentration of the thiophene-based conductive resin in the coating material containing the thiophene-based conductive resin can be selected as appropriate according to the purposes without limitation as long as the sheet resistance defined in the present invention is satisfied.

For example, when commercially available VERAZOL or SEPLEGYDA is used as the coating material containing a thiophene-based conductive resin, VERAZOL or SEPLEGYDA may be diluted with water or alcohol, and the coating layer can be formed using the diluted coating material.

The commercially available VERAZOL or SEPLEGYDA may be used as it is (dilution factor of 1). For example, VERAZOL or SEPLEGYDA may be mixed with the same amount of water or alcohol and a two-fold diluted solution (dilution factor of 2) may be used, or a solution with a dilution factor of more than two may be used.

The conditions for applying a coating material containing a thiophene-based conductive resin can be selected as appropriate according to the purposes without limitation as long as the sheet resistance defined in the present invention is satisfied.

For example, when commercially available VERAZOL or SEPLEGYDA is used as the coating material containing a thiophene-based conductive resin, coating can be performed using a spin coater (MS-A200 from Mikasa Co., Ltd.) at 100 rpm to 2,000 rpm for 15 to 60 sec. More preferably, coating can be performed at 1,000 rpm for 15 sec. When commercially available VERAZOL or SEPLEGYDA is used, coating can be performed using a spray coater (rCoater from ASAHI SUNAC CORPORATION), for example, with an ejection amount of 1 to 10 mL/min.

The drying condition for the applied coating film can be selected as appropriate according to the purposes without limitation as long as the sheet resistance defined in the present invention is satisfied.

For example, when VERAZOL is used as a coating material containing a thiophene-based conductive resin, the drying condition may be 80° C. to 100° C. for 1 to 5 minutes, more preferably 90° C. for 5 minutes. When SEPLEGYDA is used, the drying condition may be 100° C. to 150° C. for 20 to 60 minutes, more preferably 120° C. for 30 minutes.

When the photomask of the present invention has the resin covering layer on the coating layer including a thiophene-based conductive resin, the photomask of the present invention having the resin covering layer is manufactured by further forming the resin covering layer on the coating layer including a thiophene-based conductive resin.

As a method of forming the resin covering layer on the coating layer including a thiophene-based conductive resin, a coating material containing a resin for forming the resin covering layer is applied on the coating layer including a thiophene-based conductive resin. As a coating method, a common coating method such as spin coating, spray coating, dip coating, or curtain coating can be used.

(Method of Manufacturing Electronic Component)

The photomask of the present invention can be used as a photomask for printed wiring boards, semiconductors, and a variety of other electronic components for use in manufacturing electronic components such as printed wiring and semiconductor circuits.

A photoresist can be exposed using the photomask so that the exposure pattern of the photomask is transferred to the photoresist.

A circuit pattern in printed wiring or a semiconductor circuit can be formed through an exposure process using the photomask of the present invention.

A preferable embodiment of the method of manufacturing an electronic component in which an electronic component is manufactured through an exposure process using the photomask of the present invention is, for example, the following manufacturing method.

A method of manufacturing an electronic component includes: forming a resist film on a substrate; exposing the resist film through the photomask of the present invention; forming a resist pattern by developing the exposed resist film; etching the substrate using the resist pattern as a mask; and removing the resist pattern.

Commonly known techniques can be employed in the steps described above.

The method of manufacturing an electronic component according to the present invention includes the step of performing exposure for the resist film formed on a process target layer for manufacturing an electronic component, using the photomask of the present invention as described above.

Since the photomask of the present invention with high durability that causes no destruction of the exposure pattern is used, satisfactory electronic components can be stably manufactured even when the photomask is repeatedly used.

The electronic component manufactured using the photomask of the present invention is a satisfactory electronic component.

Examples of the electronic component manufactured using the photomask of the present invention include electronic components such as printed wiring boards and semiconductor circuits, more specifically, metal masks, primary mounting package prober substrates, tape automated bonding (TAB), chip on film (COF), micro electro mechanical systems (MEMS: integrated devices), sensors, liquid crystal displays (LCD), electroluminescence devices (EL), CPUs, micro-processing units (MPU), dynamic random access memory (DRAM), field-programmable gate arrays (FPGA), and system LSIs.

The exposure using the photomask of the present invention to transfer the exposure pattern of the photomask to a photoresist may be performed by any method using a transfer device conventionally used. For example, a projection exposure device, a proximity exposure device, or a soft/hard contact exposure device can be used.

Radiation light of the exposure device used in exposure can be selected as appropriate according to the purposes without limitation and, for example, preferably includes one of i-line, h-line, and g-line. A light source with a wavelength range including a plurality of wavelengths among them, more preferably all of i-line, h-line, and g-line can be used.

### EXAMPLES

The present invention is described in detail below with examples. However, the scope of the present invention is not limited by these examples.

### Example 1

A photomask comprising a light-shielding film of chromium (Cr) formed on soda-lime glass (101.6 mm×101.6 mm×3 mm) was prepared. The film thickness of chromium (Cr) was 100 nm.

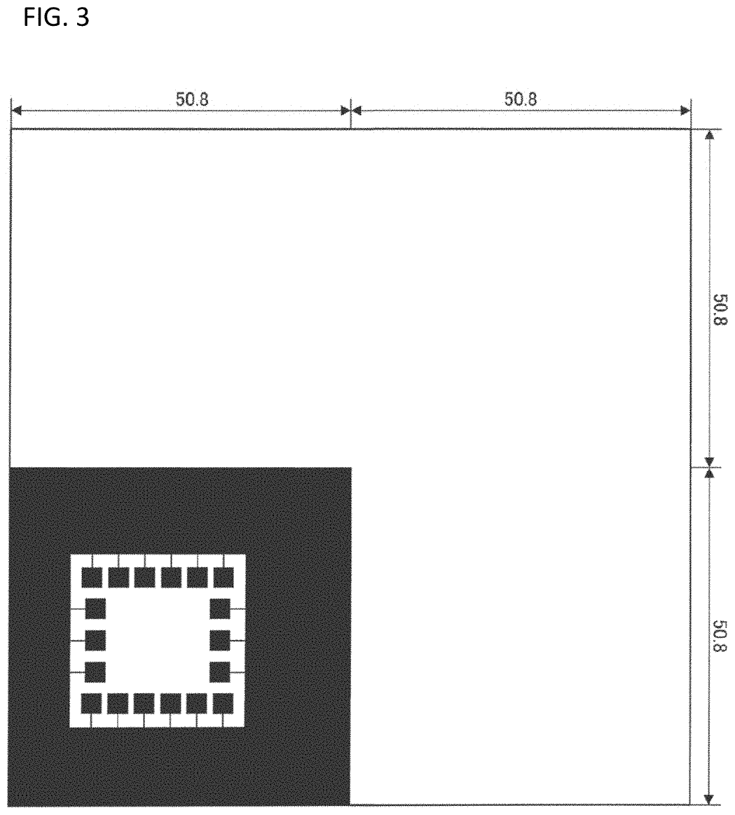

The pattern of chromium is as illustrated in FIG. 3. In FIG. 3, a black portion depicts a portion in which the chromium mask pattern is formed.

Alkaline solution cleaning and brush scrub cleaning were performed for the soda-lime glass having the chromium (Cr) light-shielding film.

A coating material SEPLEGYDA (ASZ-B03 from Shin-Etsu Polymer Co., Ltd.) by a dilution factor of 1 was applied to the soda-lime glass having the chromium (Cr) light-shielding film by spray coating. As a spray coater, rCoater from ASAHI SUNAC CORPORATION was used. The ejection amount of the coating material SEPLEGYDA was 10 mL/min.

The coating film of SEPLEGYDA was dried at 120° C. for 30 minutes.

<Measurement of Sheet Resistance>

The sheet resistance was measured using an edge portion where the chromium mask pattern was not formed in the photomask having the coating layer of SEPLEGYDA fabricated as described above.

The sheet resistance was measured using a 4-point probe system MCP-T610 from Mitsubishi Chemical Analytech Co., Ltd. when the sheet resistance was smaller than 10⁷Ω/□, and using a ring electrode system MCP-HT450 from Mitsubishi Chemical Analytech Co., Ltd. when the sheet resistance was 10⁷Ω/□ or higher.

The measurement results are listed in Table 1.

<Measurement of Transmittance>

The transmittance to light having a wavelength of 365 nm was measured for the photomask having the coating layer of SEPLEGYDA fabricated as described above.

The transmittance (%) was measured using a spectrophotometer V-570 from JASCO Corporation.

The evaluation results are listed in Table 1.

<Evaluation of Degree of Destruction of Photomask>

Subsequently, a voltage of 10 kV was applied to the photomask having the coating layer of SEPLEGYDA fabricated as described above by applying air ions generated by corona discharge using a static electricity generator (GC90 from Green-Techno Inc.).

For the photomask after voltage application, the degree of destruction of the photomask was determined through observation with a microscope.

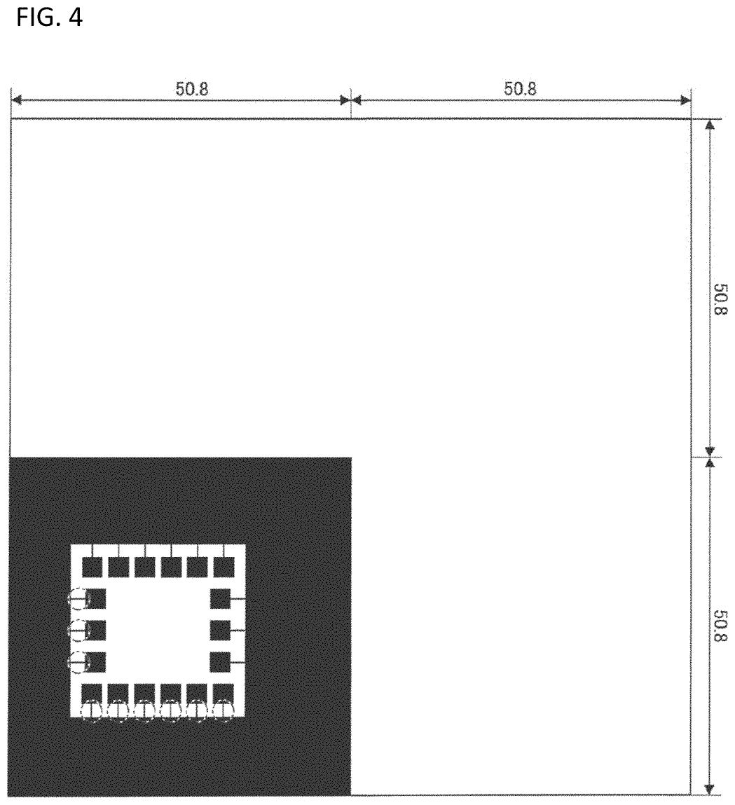

In the photomask in FIG. 4, the state of the Cr mask pattern was observed at sections each surrounded by a circle. Although nine sections are surrounded by circles in FIG. 4, the Cr mask pattern was observed similarly at 18 sections in total disposed between the Cr light-shielding film on the outer periphery and the Cr light-shielding film on the inside.

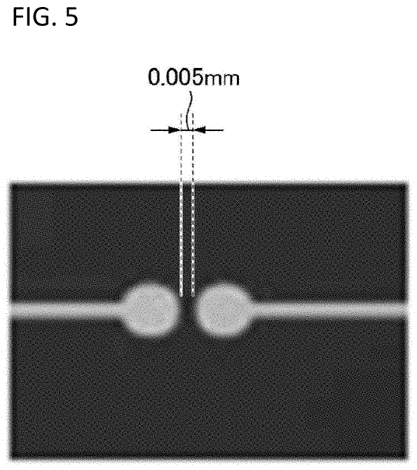

In the photomask in FIG. 4, the Cr mask pattern at a section surrounded by a circle has a shape illustrated in FIG. 5. In FIG. 5, the gap in the mask pattern (the length between the round portions) is 0.005 mm.

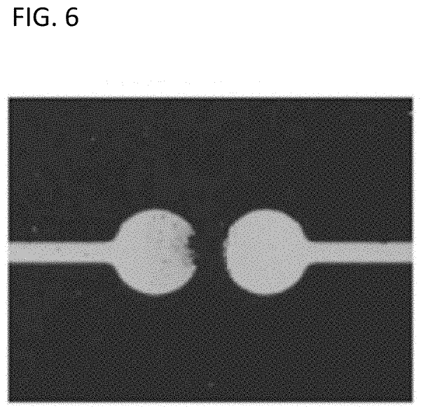

When destruction occurs in the Cr mask pattern in the photomask after voltage application, for example, the state of the Cr mask pattern is as illustrated in FIG. 6.

For the photomask after voltage application by a static electricity generator, the state of the mask pattern was observed with a microscope to determine whether destruction occurred in the mask pattern.

The microscope used was OLS4100 from Olympus Corporation.

Whether destruction occurred in the mask pattern was determined, and the proportion of the mask pattern free from destruction was determined. The proportion of the mask pattern free from destruction was determined where 100% indicates no destruction and 0% indicates destruction at all of 18 sections. Figures below the decimal point are omitted.

<Overall Evaluation>

The photomask was evaluated by the criterion below, based on the transmittance and the degree of destruction of the mask pattern by voltage application. The results are listed in Table 1.

6: The transmittance is 85% or higher and no destruction occurs in the Cr mask pattern.

5: The transmittance is 80% or higher and no destruction occurs in the Cr mask pattern.

4: The transmittance is 80% or higher. Almost no destruction occurs in the Cr mask pattern.

3: The transmittance is 80% or higher. Destruction occurs in the Cr mask pattern in many cases.

2: The transmittance is lower than 80% or destruction occurs in all of the Cr mask pattern.

1: The transmittance is lower than 80% and destruction occurs in all of the Cr mask pattern.

### Examples 2 to 10

Photomasks of Examples 2 to 10 were fabricated in the same manner as in Example 1 except that the kind of thiophene-based conductive resin, the dilution factor of the coating material of thiophene-based conductive resin, the kind of coating method, and the coating conditions in Example 1 were changed as indicated in Table 1 and the drying condition (temperature, time) of the coating layer of the thiophene-based conductive resin was adjusted as appropriate.

In Example 5 and others, a coating material of SEPLEGYDA (AS-M04D from Shin-Etsu Polymer Co., Ltd.) was used as the coating material of thiophene-based conductive resin.

In Example 10, the coating material of thiophene-based conductive resin was spin-coated using a spin coater (MS-A200 from Mikasa Co., Ltd.) under the coating conditions: a spinning speed of 300 rpm and a liquid amount of 1.5 mL.

Measurement and evaluation similar to those of Example 1 were performed for the fabricated photomasks.

The results are listed in Table 1.

### Comparative Examples 1 to 3

Photomasks of Comparative Examples 1 to 3 were fabricated in the same manner as in Example 1 except that the kind of thiophene-based conductive resin, the dilution factor of the coating material of thiophene-based conductive resin, the kind of coating method, and the coating conditions in Example 1 were changed as indicated in Table 1 and the drying condition (temperature, time) of the coating layer of the thiophene-based conductive resin was adjusted as appropriate.

In the photomask of Comparative Example 3, a coating layer including a thiophene-based conductive resin was not formed.

Measurement and evaluation similar to those of Example 1 were performed for the fabricated photomasks.

The results are listed in Table 1.

### Example 11

A photomask having a coating layer including a thiophene-based conductive resin was fabricated under conditions similar to those in Example 2. The sheet resistance of the photomask is listed in Table 2.

Furthermore, in the photomask, a resin covering layer including polyester resin was further formed by spin coating on the coating layer including a thiophene-based conductive resin.

A polyester resin (TOP'S-N) from TOPIC Co., Ltd. was used as the polyester resin.

Using a spin coater (MS-A200 from Mikasa Co., Ltd.), 1.5 mL of a coating material of the polyester resin set to a desired concentration was spin-coated at 400 rpm.

The heating condition for a coating film of the polyester resin was adjusted to form a covering layer of the polyester resin having a film thickness of 2 μm to 3 μm.

For the photomask having the covering resin layer fabricated in Example 11, the transmittance was measured in the same manner as in Example 1. Furthermore, a voltage of 10 kV was applied to the photomask by applying air ions generated by corona discharge using a static electricity generator (GC90 from Green-Techno Inc.), in the same manner as in <Evaluation of Degree of Destruction of Photomask> described in Example 1.

For the photomask after voltage application, the degree of destruction of the photomask was determined through observation with a microscope.

The result of the degree of destruction of the photomask is listed in Table 2.

### Example 12

A photomask having a coating layer including a thiophene-based conductive resin was fabricated under conditions similar to those in Example 5. The sheet resistance of the photomask is listed in Table 2.

Furthermore, in the photomask, a resin covering layer including polyester resin was further formed by spin coating on the coating layer including a thiophene-based conductive resin in the same manner as in Example 11.

For the photomask having the covering resin layer fabricated in Example 12, the transmittance and the degree of destruction of the photomask were determined in the same manner as in Example 11.

The result of the degree of destruction of the photomask is listed in Table 2.

### Example 13

A photomask having a coating layer including a thiophene-based conductive resin was fabricated under conditions similar to those in Example 6. The sheet resistance of the photomask is listed in Table 2.

Furthermore, in the photomask, a resin covering layer including polyester resin was further formed by spin coating on the coating layer including a thiophene-based conductive resin in the same manner as in Example 11.

For the photomask having the covering resin layer fabricated in Example 13, the transmittance and the degree of destruction of the photomask were determined in the same manner as in Example 11.

The result of the degree of destruction of the photomask is listed in Table 2.

### Comparative Example 4

A photomask having a coating layer including a thiophene-based conductive resin was fabricated under conditions similar to those in Comparative Example 1. The sheet resistance of the photomask is listed in Table 2.

Furthermore, in the photomask, a resin covering layer including polyester resin was further formed by spin coating on the coating layer including a thiophene-based conductive resin in the same manner as in Example 11.

For the photomask having the covering resin layer fabricated in Comparative Example 4, the transmittance and the degree of destruction of the photomask were determined in the same manner as in Example 11.

The result of the degree of destruction of the photomask is listed in Table 2.

### Comparative Example 5

A photomask not having a coating layer including a thiophene-based conductive resin was fabricated under conditions similar to those in Comparative Example 3. The sheet resistance of the photomask is listed in Table 2.

Furthermore, in the photomask, a resin covering layer including polyester resin was further formed by spin coating on soda-lime glass having a Cr light-shielding film in the same manner as in Example 11.

For the photomask fabricated in Comparative Example 5, the transmittance and the degree of destruction of the photomask were determined in the same manner as in Example 11.

The result of the degree of destruction of the photomask is listed in Table 2.

TABLE 1

| | | | | Conditions | | | | | | | |
|---|---|---|---|---|---|---|---|---|---|---|---|
| | | | | spray | | | | | | | |
| | | | | ejection | | | | | | | |
| | | | | amount/ | | | | | | | |
| | | | | spinning | | ESD | | | | | |
| | | | | speed and | | layer | Static | Sheet | Transmit- | No | Overall |
| | SEPLEGYDA | SEPLEGYDA | Dilution | liquid | | coating | electricity | resis- | tance (%) | destruc- | evalua- |
| | AS-M04D | ASZ-B03 | factor | amount | | method | condition | tance | (365 nm) | tion % | tion |
| Example 1 | | ∘ | 1 | 10 | mL/min | Spray | 10 kV | 2.69E+02 | 84.8 | 100 | 5 |
| Example 2 | | ∘ | 1 | 5 | mL/min | Spray | 10 kV | 7.23E+02 | 85.9 | 100 | 6 |
| Example 3 | | ∘ | 1 | 2 | mL/min | Spray | 10 kV | 2.34E+03 | 86.6 | 100 | 6 |
| Example 4 | | ∘ | 2 | 3 | mL/min | Spray | 10 kV | 5.38E+03 | 86.8 | 100 | 6 |
| Example 5 | ∘ | | 1 | 10 | mL/min | Spray | 10 kV | 9.02E+05 | 85.7 | 100 | 6 |
| Example 6 | ∘ | | 1 | 6 | mL/min | Spray | 10 kV | 2.84E+06 | 86.2 | 100 | 6 |
| Example 7 | ∘ | | 1 | 5 | mL/min | Spray | 10 kV | 7.97E+06 | 86.5 | 100 | 6 |
| Example 8 | ∘ | | 1 | 3 | mL/min | Spray | 10 kV | 1.44E+08 | 86.8 | 100 | 6 |
| Example 9 | ∘ | | 2 | 5 | mL/min | Spray | 10 kV | 2.46E+08 | 86.9 | 100 | 6 |

| | | | | | | | | | |
|---|---|---|---|---|---|---|---|---|---|
| Example 10 | ∘ | 3 | 300 rpm, | Spin | 10 kV | 1.37E+10 | 87.1 | 100 | 6 |
| | | | 1.5 mL | | | | | | |
| Comparative | ∘ | 3 | 600 rpm, | Spin | 10 kV | 5.88E+11 | 87.2 | 0 | 2 |
| Example 1 | | | 1.5 mL | | | | | | |
| Comparative | ∘ | 3 | 800 rpm, | Spin | 10 kV | 3.64E+12 | 87.3 | 0 | 2 |
| Example 2 | | | 1.5 mL | | | | | | |
| Comparative | | | — | None | 10 kV | 3.65E+12 | 87.6 | 0 | 2 |
| Example 3 | | | | | | | | | |

TABLE 2

| | | | | Conditions | | | | | | | | |
|---|---|---|---|---|---|---|---|---|---|---|---|---|
| | | | | spray | | | | | | | | |
| | | | | ejection | | | | | | | | |
| | | | | amount/ | | | | | | | Resin | |
| | | | | spinning | | ESD | | | | | covering | |
| | | | | speed and | | layer | Static | Sheet | Transmit- | No | layer of | Overall |
| | SEPLEGYDA | SEPLEGYDA | Dilution | liquid | | coating | electricity | resis- | tance (%) | destruc- | polyester | evalua- |
| | AS-M04D | ASZ-B03 | factor | amount | | method | condition | tance | (365 nm) | tion % | resin | tion |
| Example 11 | | ∘ | 1 | 5 | mL/min | Spray | 10 kV | 7.23E+02 | 86.0 | 100 | Applied | 6 |
| Example 12 | ∘ | | 1 | 10 | mL/min | Spray | 10 kV | 9.02E+05 | 86.1 | 100 | Applied | 6 |
| Example 13 | ∘ | | 1 | 6 | mL/min | Spray | 10 kV | 2.84E+06 | 86.7 | 100 | Applied | 6 |

| | | | | | | | | | | |
|---|---|---|---|---|---|---|---|---|---|---|
| Comparative | ∘ | 3 | 600 rpm, | Spin | 10 kV | 5.88E+11 | 87.6 | 11 | Applied | 3 |
| Example 4 | | | 1.5 mL | | | | | | | |
| Comparative | | | — | None | 10 kV | 3.65E+12 | 87.8 | 0 | Applied | 2 |
| Example 3 | | | | | | | | | | |

Examples demonstrate that the present invention can provide a photomask having sufficient durability against electrostatic discharge.

The photomask of the present invention can be used to prevent destruction of the exposure pattern and suppress electrostatic discharge of the mask pattern.

In addition, the photomask of the present invention exhibits excellent light transmittance.

The photomask of the present invention is therefore a photomask excellent in durability and exposure efficiency.

### REFERENCE SIGNS LIST

1 transparent substrate
2 light-shielding film
3 coating layer including conductive resin
4 resin covering layer (overcoat layer)

1. A photomask comprising a light-shielding film formed on a surface of a transparent substrate, the light-shielding film being formed into a pattern for shielding a photoresist film from exposure to light, wherein
the transparent substrate having the light-shielding film formed thereon has a coating layer including a thiophene-based conductive resin, and
a sheet resistance at a surface of the photomask having the coating layer including a thiophene-based conductive resin is smaller than 10¹¹Ω/□.

2. The photomask according to claim 1, wherein the photomask having the coating layer including a thiophene-based conductive resin has a transmittance of 80% or higher to light having a wavelength of 365 nm.

3. The photomask according to claim 1, further comprising a resin covering layer on the coating layer including a thiophene-based conductive resin.

4. A method of manufacturing the photomask according to claim 1, the method comprising, in a photomask comprising a light-shielding film formed into a pattern for shielding a photoresist film from exposure to light, formed on a surface of a transparent substrate, forming a coating layer including a thiophene-based conductive resin, on the transparent substrate having the light-shielding film formed thereon.

5. The method of manufacturing the photomask according to claim 4, further comprising forming a resin covering layer on the coating layer including a thiophene-based conductive resin.

6. A method of manufacturing an electronic component, the method comprising performing exposure using the photomask according to claim 1.

7. An electronic component manufactured using the photomask according to claim 1.
